(19) United States
(12) Patent Application Publication
(10) Pub. No.: US 2014/0014815 A1
(43) Pub. Date: Jan. 16, 2014

(54) RAMP SIGNAL GENERATOR FOR CMOS IMAGE SENSOR

(71) Applicant: SAMSUNG ELECTRONICS CO., LTD., Suwon-si (KR)

(72) Inventors: Hyeok-jong LEE, Yongin-si (KR); Yun-jung KIM, Yongin-si (KR); Jin-uk JEON, Ansan-si (KR); Ji-min CHEON, Yongin-si (KR); Jin-ho SEO, Seoul (KR); Seog-heon HAM, Suwon-si (KR)

(73) Assignee: SAMSUNG ELECTRONICS CO., LTD., Suwon-si (KR)

(21) Appl. No.: 13/837,501

(22) Filed: Mar. 15, 2013

(30) Foreign Application Priority Data
Jul. 16, 2012 (KR) 10-2012-0077364

(51) Int. Cl. H03K 4/02; H04N 5/376

(52) U.S. Cl. CPC H03K 4/026; H04N 5/3765
USPC 250/208.1; 327/126

(57) ABSTRACT

A ramp signal generator includes: a row decoder which receives a row control signal from a timing controller and generates one or more row select signals, a first column decoder which receives a first column control signal from the timing controller and generates one or more first column select signals, a second column decoder which receives a second column control signal from the timing controller and generates one or more second column select signals, and a current cell array which is activated by the one or more first column select signals, the one or more second column select signals, and the one or more row select signals, and includes at least one current cell which generates at least one unit current, and generates an output current by summing the generated at least one unit current.

### CROSS-REFERENCE TO RELATED APPLICATIONS

This application claims priority from Korean Patent Application No. 10-2012-0077364, filed on Jul. 16, 2012, in the Korean Intellectual Property Office, the disclosure of which is incorporated herein in its entirety by reference.

### BACKGROUND

Exemplary embodiments relate to a ramp signal generator for a complementary metal-oxide-semiconductor (CMOS) image sensor. More particularly, exemplary embodiments relate to a ramp signal generator for a CMOS image sensor using a single-slope analog-to-digital converter.

Current CMOS image sensors (CIS) require a high pixel and a high frame rate in a motion picture mode for high image quality. A single-slope analog-to-digital (A/D) converter uses a ramp signal generator for generating a ramp signal. The ramp signal is used as a reference signal for an A/D converter. In order for a single-slope A/D converter to operate at high speed, clock frequencies need to be increased. However, increasing clock frequencies results in a large amount of power being consumed.

### SUMMARY

Exemplary embodiments provide a ramp signal generator that consumes a relatively small amount of power, while a single-slope analog-to-digital converter operates at high speed.

According to an aspect of an exemplary embodiment, there is provided a ramp signal generator including a row decoder which receives a row control signal from a timing controller and generates one or more row select signals, a first column decoder which receives a first column control signal from the timing controller and generates one or more first column select signals, a second column decoder which receives a second column control signal from the timing controller and generates one or more second column select signals, and a current cell array which is activated by the one or more first column select signals, the one or more second column select signals, and the one or more row select signals, includes at least one current cell which generates at least one unit current, and generates an output current by summing the generated at least one unit current, wherein the one or more first column select signals and the one or more second column select signals activate current cells included in different rows.

The one or more first column select signals may activate the current cells in an odd-numbered row of the current cell array, and the one or more second column select signals may activate the current cells in an even-numbered row of the current cell array.

The at least one current cell may continuously generates the at least one unit current even when the one or more first column select signals, the one or more second column select signals, and the one or more row select signals are deactivated.

The ramp signal generator may further include a current-voltage converter that converts the output current of the current cell array to a ramp signal.

The current cell array may include one or more current cells in m-numbered rows and n-numbered columns, the first column decoder may turn on the current cells in a first row in order from a first column to an n-th column, and the second column decoder may turn on the current cells in a second row in order from the n-th column to the first column.

The ramp signal generator may further include a third column decoder which receives a third column control signal from the timing controller and generates one or more third column select signals, and a fourth column decoder which receives a fourth column control signal from the timing controller and generates one or more fourth column select signals, wherein the third column decoder turns on the current cells in a third row in order from the first column to the n-th column, and the fourth column decoder turns on the current cells in a fourth column in order from the n-th column to the first column.

A number of the one or more first column select signals and the one or more second column select signals may correspond to a number of the current cells included in the current cell array belonging to a same row.

The first column decoder and the second column decoder may do not respectively simultaneously deactivate the one or more first column select signals and the one or more second column select signals corresponding to the current cells.

The first column decoder and the second column decoder may deactivate the one or more first column select signals and the one or more second column select signals respectively, corresponding to the current cells in order of the activation of the current cells.

Each of the current cells may include a switching signal generating unit which activates a switching signal in response to the one or more first column select signals, the one or more second column select signals, and the one or more row select signals, and maintaining an active state of the switching signal; and a unit current providing unit which provides the unit current in response to the switching signal.

The switching signal generating unit may include a row select switch which is turned on in response to the one or more row select signals, a column select switch which is serially connected to the one or more row select switch and turned on in response to the one or more first column select signals or the one or more second column select signals, and a memory circuit which activates the switching signal and maintains the active state of the switching signal when the row select switch and the column select switch are turned on.

The switching signal generating unit may further include a reset switch which is turned on in response to a reset signal, and the memory circuit may deactivate the switching signal when the reset switch is turned on.

The unit current providing unit may include a unit current source which provides the unit current, and a current providing switch which connects the unit current source to a current-voltage converter which converts the output current of the current cell array to a ramp signal.

According to another aspect of another exemplary embodiment, there is provided an image sensor including: the above ramp signal generator, one or more photosensing cells which converts incident light to an electric signal, a row driver which generates a drive signal to activate the one or more photosensing cells in units of rows, a ramp signal generator which generates a ramp signal as a voltage signal, a counter which generates a counting signal corresponding to the ramp signal, a comparator array which connects to the one or more photosensing cells in a column direction and compares the electric signal to the ramp signal, a latch array which stores the counting signal corresponding to an output signal of the comparator array, and a timing controller which provides control signals to the row driver, the ramp signal generator, the counter, the comparator array, and the latch array.

The first column decoder and the second column decoder may do not respectively simultaneously deactivate the one or more first column select signals and the one or more second column select signals, corresponding to the current cells when the one or more first column select signals and the one or more second column select signals are deactivated.

According to another aspect of another exemplary embodiment, there is provided a method of generating a ramp signal including receiving a row control signal, and generating one or more row select signals, receiving a first column control signal, and generating one or more first column select signals, receiving a second column control signal, and generating one or more second column select signals, activating a current cell array by the one or more first column select signals, the one or more second column select signals, and the one or more row select signals, generating at least one unit current, and generating an output current by summing the generated at least one unit current, wherein the one or more first column select signals, the one or more second column select signals activate current cells included in different rows.

### BRIEF DESCRIPTION OF THE DRAWINGS

Exemplary embodiments will be more clearly understood from the following detailed description taken in conjunction with the accompanying drawings in which:

FIG. 1 is a block diagram illustrating a ramp signal generator according to an exemplary embodiment;

FIG. 2 is a block diagram illustrating a current cell included in the ramp signal generator of FIG. 1;

FIG. 3A is a circuit diagram illustrating an example of the current cell of FIG. 2;

FIG. 3B is a circuit diagram illustrating another example of the current cell of FIG. 2;

FIG. 4A is a timing diagram illustrating an operation of a ramp signal generator, according to an exemplary embodiment;

FIG. 4B is a timing diagram illustrating an operation of a ramp signal generator, according to another exemplary embodiment;

FIG. 4C is a timing diagram illustrating an operation of a ramp signal generator, according to another exemplary embodiment;

FIG. 5 is a block diagram illustrating an image sensor according to an exemplary embodiment; and

FIG. 6 is a block diagram illustrating an applied example of an electronic system including the ramp signal generator.

### DETAILED DESCRIPTION OF THE EXEMPLARY EMBODIMENTS

Exemplary embodiments are described in detail with reference to the accompanying drawings. However, the exemplary embodiments are not limited thereto, and it will be understood that various changes in form and details may be made therein without departing from the spirit and scope of the following claims. In other words, descriptions of particular structures or functions may be presented merely for explaining exemplary embodiments. Throughout the drawings, like reference numerals denote like elements.

The terms used in the present specification are used for explaining a specific exemplary embodiment, and do not limit the exemplary embodiments. Thus, the expression of a singularity in the present specification includes the expression of a plurality, unless clearly specified otherwise in context. Also, the terms such as “include” or “comprise” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

Terms such as “first” and “second” are used herein merely to describe a variety of constituent elements, but the constituent elements are not limited by the terms. These terms are used only for the purpose of distinguishing one constituent element from another constituent element. For example, without departing from the right scope of the exemplary embodiments, a first constituent element may be referred to as a second constituent element, and vice versa.

Unless defined otherwise, all terms used herein including technical or scientific terms have the same meanings as those generally understood by those of ordinary skill in the art to which the present exemplary embodiments may pertain. The terms, as those defined in generally used dictionaries, are construed to have meanings matching that in the context of the related technology and, unless clearly defined otherwise, are not construed to be ideally or excessively formal.

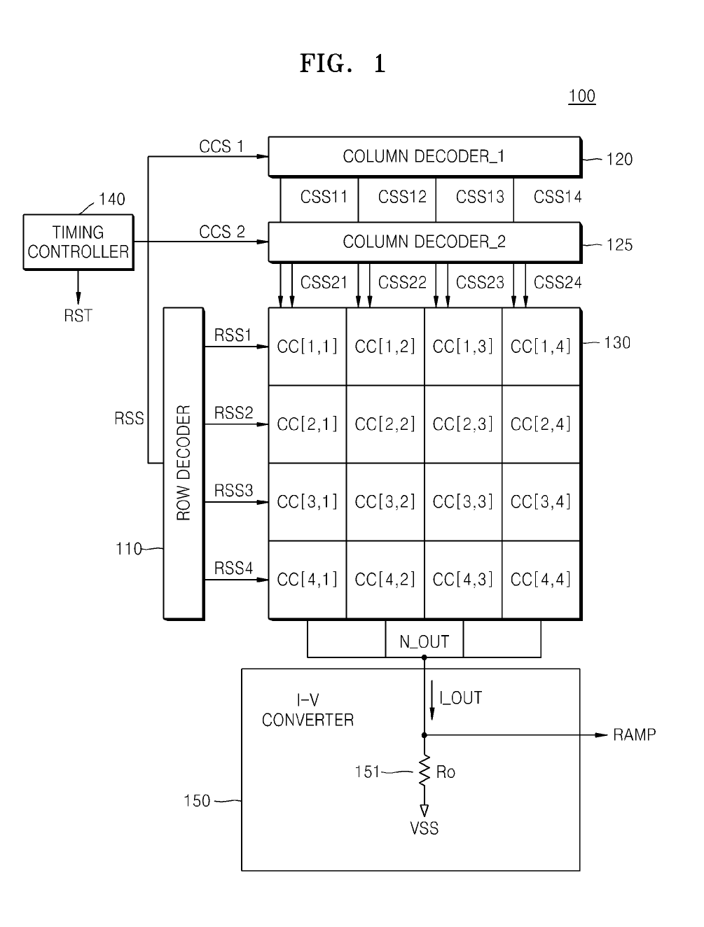

FIG. 1 is a block diagram illustrating a ramp signal generator 100 according to an exemplary embodiment. Referring to FIG. 1, the ramp signal generator 100 may include a row decoder (ROW DECODER) 110, a first column decoder (COLUMN DECORDER_{—}1) 120, a second column decoder (COLUMN DECORDER_{—}2) 125, a current cell array (CURRENT CELL ARRAY) 130, a timing controller (TIMING CONTROLLER) 140, and a current-voltage converter (I-V CONVERTER) 150.

The timing controller 140 generates a row control signal RCS, a first column control signal CCS_{—}1, and a second column control signal CCS_{—}2. The row control signal RCS is input to the row decoder 110. The first column control signal CCS_{—}1 is input to the first column decoder 120. The second column control signal CCS_{—}2 is input to the second column decoder 125.

The timing controller 140 may store control information in a cache buffer (not shown). The timing controller 140 may generate the row control signal RCS, the first column control signal CCS_{—}1, and the second column control signal CCS_{—}2, based on the control information. The cache buffer may be a synchronous random access memory (SRAM).

Also, the timing controller 140 may receive the control information from a host. The timing controller 140 may receive the control information from a host through a host interface.

The host interface may include various interface protocols such as universal serial bus (USB), man machine communication (MMC), peripheral component interconnect-express (PCI-E), serial advanced technology attachment (SATA), parallel advanced technology attachment (PATA), small computer system interface (SCSI), enhanced small device interface (ESDI), and intelligent drive electronics (IDE).

The row decoder 110, in response to the row control signal RCS, generates one or more row select signals RSS1, RSS2, RSS3, and RSS4. The row decoder 110 may turn on row select transistors included in one or more current cells, corresponding to the same row in the current cell array 130, within a same time period. For example, the row decoder 110 may activate the row select signal RSS1 in a first time period to turn on row select transistors, included in current cells CC[1,1], CC[1,2], CC[1,3], and CC[1,4] of a first row.

The first column decoder 120, in response to the first column control signal CCS_{—}1, generates one or more first column select signals CSS11, CSS12, CSS13, and CSS14. The first column decoder 120 may turn on column select transistors included in one or more current cells corresponding to the same column of some rows, for example, odd-numbered rows, in the current cell array 130 in the same time period. For example, the first column decoder 120 may generate the first column select signal CSS11 and turn on column select transistors included in current cells CC[1,1] and CC[3,1], corresponding to the first column of the first and third rows in the same time period.

In the present exemplary embodiment, the first column decoder 120 may sequentially activate the first column select signals CSS11, CSS12, CSS13, and CSS14 in the first time period to sequentially turn on the column select transistors included in current cells CC[1,1], CC[1,2], CC[1,3], CC[1,4], CC[3,1], CC[3,2], CC[3,3], and CC[3,4], corresponding to the odd-numbered rows of the first through fourth columns.

The second column decoder 125, in response to the second column control signal CCS_{—}2, generates one or more second column select signals CSS21, CSS22, CSS23, and CSS24. The second column decoder 125 may turn on column select transistors included in one or more current cells corresponding to the same column of some rows, for example, even-numbered rows, in the current cell array 130 within a same time period. For example, the second column decoder 125 may generate the second column select signal CSS21 and turn on column select transistors included in current cells CC[2,1] and CC[4,1], corresponding to the first column of the second and fourth rows in the same time period.

In the present exemplary embodiment, the second column decoder 125 may sequentially activate the second column select signals CSS21, CSS22, CSS23, and CSS24 in a second time period to sequentially turn on the column select transistors included in current cells CC[2,1], CC[2,2], CC[2,3], CC[2,4], CC[4,1], CC[4,2], CC[4,3], and CC[4,4], corresponding to the even-numbered rows of the first through fourth columns.

In another exemplary embodiment, the second column decoder 125 may activate, in reverse order, the second column select signals CSS21, CSS22, CSS23, and CSS24 in the second time period to turn on in reverse order the column select transistors included in the current cells CC[2,1], CC[2,2], CC[2,3], CC[2,4], CC[4,1], CC[4,2], CC[4,3], and CC[4,4], corresponding to the even-numbered rows of the first through fourth columns.

The current cell array 130 may include one or more current cells, for example, sixteen current cells CC[1,1] through CC[4,4] in the present exemplary embodiment. However, the number of current cells is exemplary, and the embodiments are not limited thereto.

Each of the current cells CC[1,1] through CC[4,4] may be turned on in response to a corresponding one of the row select signals RSS1, RSS2, RSS3, and RSS4, and a corresponding one of the first column select signals CSS11, CSS12, CSS13, and CSS14 and the second column select signals CSS21, CSS22, CSS23, and CSS24.

The current cells CC[1,1] through CC[4,4] are all connected to a current output node N_OUT. Thus, the current cell array 130 may supply output current LOUT that is a sum of unit currents output from the current cells CC[1,1] through CC[4,4], to the current-voltage converter 150. In the present specification, the unit current signifies the amount of current generated by an optical signal in each current cell. The current cells CC[1,1] through CC[4,4] may be sequentially turned on.

When the current cells CC[1,1] through CC[4,4] are turned on, each of the current cells CC[1,1] through CC[4,4] may provide a unit current of the same amount. The current cell array 130 may supply the output current LOUT that increases according to time, to the current-voltage converter 150. When any one of the current cells CC[1,1] through CC[4,4] is turned on, the current cell may continuously supply the unit current until the current cell is reset.

The current-voltage converter 150 converts the output current LOUT of the current cell array 130 to a ramp signal RAMP. The current-voltage converter 150 may include an output load 151 connected between the current output node N_OUT and a power voltage VSS. The output current LOUT of the current cell array 130 is applied to the output load 151. The output load 151 may convert the output current LOUT of the current cell array 130 to the ramp signal RAMP. In the present exemplary embodiment, the output load 151 may be a resistive element. In the present exemplary embodiment, the power voltage VSS may be a low power voltage. In another exemplary embodiment, the output load 151 may be connected between the current output node N_OUT and a high power voltage, and the ramp signal RAMP may decrease as time passes. The ramp signal RAMP is compared by a comparator (not shown) with an electric signal converted by photosensing cells of a complementary metal-oxide-semiconductor (CMOS) image sensor (CIS) (not shown), and used as a reference for measuring incident light.

In the operation of the ramp signal generator 100, the row select signals RSS1, RSS2, RSS3, and RSS4 may be sequentially activated in the present exemplary embodiment. While any one of the row select signals RSS1, RSS2, RSS3, and RSS4 is activated, the first column select signals CSS11, CSS12, CSS13, and CSS14 may be sequentially activated. For example, when the first column select signals CSS11, CSS12, CSS13, and CSS14 are sequentially activated while the row select signal RSS1 is activated, the current cells CC[1,1] through CC[1,4] may sequentially generate unit currents.

Also, while another row select signal of the row select signals RSS1, RSS2, RSS3, and RSS4 is activated, the second column select signals CSS21, CSS22, CSS23, and CSS24 may be activated. For example, when the second column select signals CSS21, CSS22, CSS23, and CSS24 are sequentially activated while the row select signal RSS2 is activated, the current cells CC[2,1] through CC[2,4] may sequentially generate unit currents.

In a high image quality CIS operating at a high speed, if the time for activating the first column select signals CSS11, CSS12, CSS13, and CSS14 is short, a malfunction may occur in which any one of the current cells CC[1,1] through CC[4,4] may not be turned on.

In the present exemplary embodiment, the timing controller 140 of the ramp signal generator 100 may generate the first column control signal CCS_{—}1 and the second column control signal CCS_{—}2 to make the activation time of the first column select signals CSS11, CSS12, CSS13, and CSS14 and the second column select signals CSS21, CSS22, CSS23, and CSS24 sufficiently long. In another exemplary embodiment, the ramp signal generator 100 may include a plurality of column decoders to generate column select signals to make the activation time of each of a plurality of column select signals sufficiently long.

While the first row select signal RSS1 is activated, the first column select signals CSS11, CSS12, CSS13, and CSS14 are sequentially activated. Thus, the output current LOUT of the current cell array 130 are increased sequentially from being equal to the unit current to being four times the unit current. Next, when the second row select signal RSS2 is activated and the second column select signals CSS21, CSS22, CSS23, and CSS24 are sequentially activated, the current cells CC[2,1] through CC[2,4] are sequentially turned on. Accordingly, the output current LOUT of the current cell array 130 is increased sequentially from being five times the unit current to being eight times the unit current. In another exemplary embodiment, when the second row select signal RSS2 is activated and the second column select signals CSS21, CSS22, CSS23, and CSS24 are activated in reverse order, the current cells CC[1,1] through CC[4,4] are turned on in reverse order.

While the second row select signal RSS2 is activated and the second column select signals CSS21, CSS22, CSS23, and CSS24 are sequentially activated, the first column select signals CSS11, CSS12, CSS13, and CSS14 may be deactivated until the third row select signal RSS 3 is activated. Thus, the first column decoder 120 may generate the first column select signals CSS11, CSS12, CSS13, and CSS14, each having an activation duration time that is as long as that of a row select signal.

In another exemplary embodiment, while the second row select signal RSS2 is activated and the second column select signals CSS21, CSS22, CSS23, and CSS24 are sequentially activated, the first column select signals CSS11, CSS12, CSS13, and CSS14 may be sequentially or simultaneously deactivated.

When the third row select signal RSS3 is activated and the first column select signals CSS11, CSS12, CSS13, and CSS14 are sequentially activated, the ninth through twelfth current cells CC[3,1] through CC[3,4] are sequentially turned on. When the fourth row select signal RSS4 is activated and the second column select signals CSS21, CSS22, CSS23, and CSS24 are sequentially activated, the thirteenth through sixteenth current cells CC[4,1] through CC[4,4] are sequentially turned on. Accordingly, the output current LOUT of the current cell array 130 is increased sequentially from being nine times the unit current to being sixteen times the unit current. Therefore, the output current LOUT of the current cell array 130 is increased sequentially from nine times to sixteen times the unit current as time passes.

The current cells CC[4,1] through CC[4,4] may receive the same reset signal RST from an external device, for example, the timing controller 140. The current cells CC[1,1] through CC[4,4], in response to the reset signal RST, may be simultaneously turned off. When the current cells CC[1,1] through CC[4,4] are turned off, the current cells CC[1,1] through CC[4,4] may discontinue the supply of the unit currents.

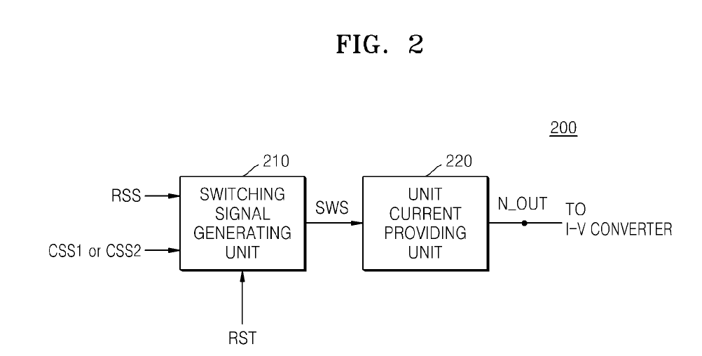

FIG. 2 is a block diagram illustrating a current cell 200 included in the ramp signal generator 100 of FIG. 1.

Referring to FIG. 2, the current cell 200 may include a switching signal generating unit 210 and a unit current providing unit 220. For example, the current cell 200 may be any one of the first through sixteenth current cells CC[1,1] through CC[4,4] of FIG. 1.

The switching signal generating unit 210, in response to a row select signal RSS, a first column select signal CSS1, and a second column select signal CSS2, may activate a switching signal SWS and maintain an active state of the switching signal SWS. The switching signal generating unit 210 operates in response to a corresponding row select signal RSS, a corresponding first column select signal CSS1, and a corresponding second column select signal CSS2.

For example, when the current cell 200 is the current cell CC[1,1] of FIG. 1, the row select signal RSS may be the row select signal RSS1 of FIG. 1. Also, the first column select signal CSS1 may be the first column select signal CSS11 of FIG. 1 When the current cell 200 is the current cell CC[4,4] of FIG. 1, the row select signal RSS may be the fourth row select signal RSS4 of FIG. 1 and the second column select signal CSS2 may be the second column select signal CSS24 of FIG. 1.

The unit current providing unit 220 is connected to the current output node N_OUT and may provide a unit current to the current-voltage converter 150 of FIG. 1 via the current output node N_OUT in response to the switching signal SWS. For example, when the switching signal SWS is in an active state, the unit current providing unit 220 may provide the unit current to the current-voltage converter 150 of FIG. 1. When the switching signal SWS is in an inactive state, the unit current providing unit 220 may discontinue the providing of the unit current to the current-voltage converter 150 of FIG. 1. In the present exemplary embodiment, the ramp signal generator 100 may include a current block path to prevent the unit current from flowing toward the output load 151 of FIG. 1, and the unit current providing unit 220 may discontinue the providing of the unit current by allowing the unit current to flow through the current block path.

The switching signal generating unit 210 activates the switching signal SWS when the corresponding row select signal RSS and the corresponding column select signal CSS1 or CSS2 are all activated. Even when both the row select signal RSS and the column select signal CSS1 or CSS2 are deactivated, the switching signal generating unit 210 may maintain the active state of the switching signal SWS. The switching signal generating unit 210 may receive the reset signal RST from an eternal apparatus. When the current cell 200 is turned off, the current cell 200 may discontinue the providing of the unit current.

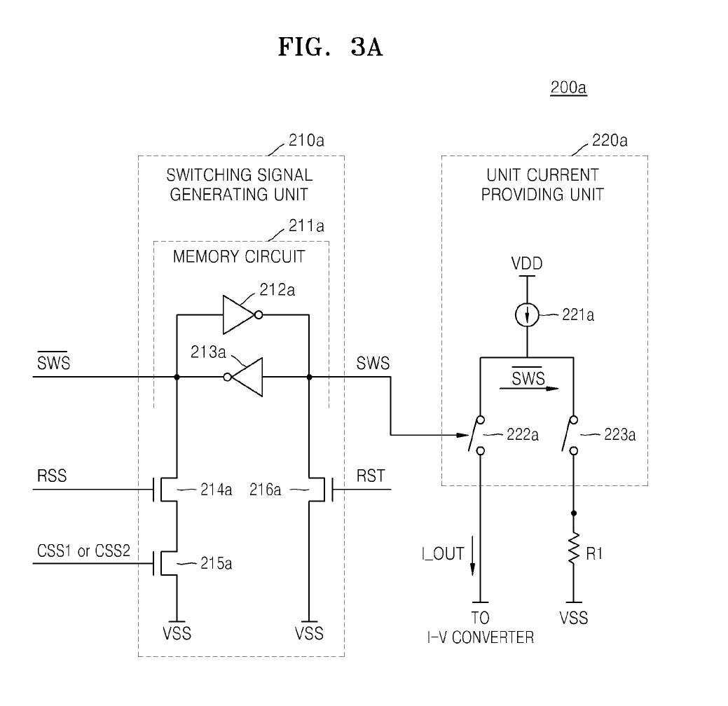

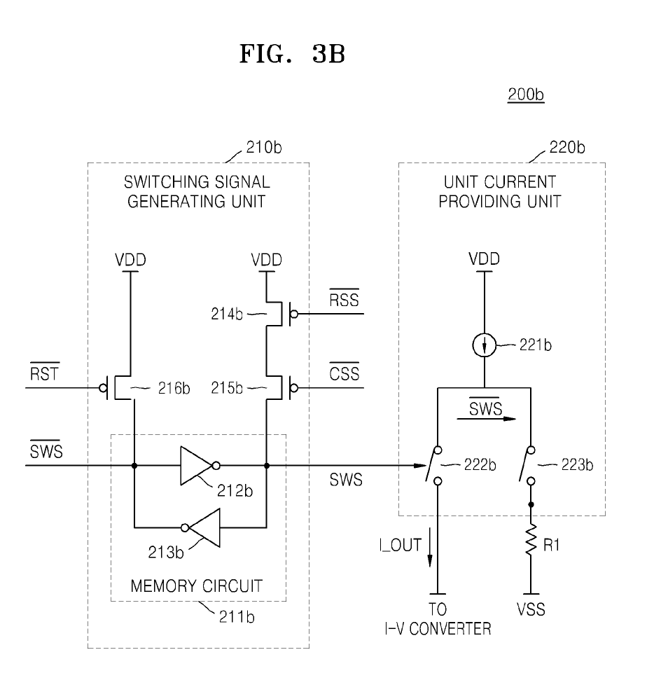

FIG. 3A is a circuit diagram illustrating an example of the current cell 200 of FIG. 2. Referring to FIG. 3A, a current cell 200a includes a switching signal generating unit 210a and a unit current providing unit 220a.

The switching signal generating unit 210a includes a memory circuit 211a, a row select transistor 214a, and a column select transistor 215a. In the present exemplary embodiment, the memory circuit 211a may be a latch circuit including a first inverter 212a and a second inverter 213a.

The row select transistor 214a may be turned on in response to the row select signal RSS. The column select transistor 215a may be turned on in response to the first column select signal CSS1 or the second column select signal CSS2. The row select transistor 214a and the column select transistor 215a may be serially connected between an input terminal of the first inverter 212a and the low power voltage VSS. For example, the row select transistor 214a may have a first drain connected to the input terminal of the first inverter 212a, a first gate to which the row select signal RSS is applied, and a first source to which a second drain of the column select transistor 215a is connected. The column select transistor 215a may have the second drain connected to the first source of the row select transistor 214a, a second gate to which the first column select signal CSS1 or the second column select signal CSS2 is applied, and a second source connected to the low power voltage VSS. In another exemplary embodiment, the column select transistor 215a may be connected to the input terminal of the first inverter 212a and the row select transistor 214a may be connected between the column select transistor 215a and the low power voltage VSS.

The memory circuit 211a may activate the switching signal SWS when both of the row select transistor 214a and the column select transistor 215a are turned on, and may maintain an active state of the switching signal SWS. For example, when the row select signal RSS and the first column select signal CSS1 are simultaneously activated or the row select signal RSS and the second column select signal CSS2 are simultaneously activated, the row select transistor 214a and the column select transistor 215a are simultaneously turned on. When the row select transistor 214a and the column select transistor 215a are simultaneously turned on, a voltage of a logic low level is applied to the input terminal of the first inverter 212a. The first inverter 212a inverts the voltage of a logic low level to generate a switching signal SWS of a logic high level. In other words, the first inverter 212a activates the switching signal SWS. The second inverter 213a inverts the switching signal SWS of a logic high level to generate an inverted switching signal SWS of a logic low level. An output terminal of the first inverter 212a is connected to an input terminal of the second inverter 213a, and an output terminal of the second inverter 213a is connected to the input terminal of the first inverter 212a. Therefore, even when the row select transistor 214a and/or the column select transistor 215a are turned off, the switching signal SWS and the inverted switching signal SWS may be maintained, respectively, at a logic high level and a logic low level by the first inverter 212a and the second inverter 213a.

The switching signal generating unit 210a may further include a reset transistor 216a. The reset transistor 216a is turned on in response to the reset signal RST. For example, the reset signal RST may be provided from an external device such as the timing controller 140. When the reset signal RST is activated, the reset transistor 216a is turned on and the switching signal SWS has a logic low level. In other words, the switching signal SWS is deactivated and the inverted switching signal SWS is activated. The switching signal generating unit 210a may be embodied by seven transistors.

The unit current providing 220a includes a unit current source 221a and a current providing switch 222a. The unit current source 221a provides a unit current. In the present exemplary embodiment, a plurality of unit current sources included in the current cells CC[1,1] through CC[4,4] of FIG. 1 may provide a plurality of unit currents that are substantially the same. The current providing switch 222a, in response to the switching signal SWS, may connect the unit current source 221a to the current-voltage converter 150 of FIG. 1. For example, when the switching signal SWS has a logic high level, the current providing switch 222a may connect the unit current source 221a to the current-voltage converter 150 of FIG. 1, and the current cell 200a may provide a unit current to the current-voltage converter 150 of FIG. 1.

The unit current providing unit 220a may further include a current block switch 223a. The current block switch 223a, in response to the inverted switch signal SWS, that is an inverted signal of the switching signal SWS, may connect the unit current source 221a to the current block path. The current block path may include a resistor R1. For example, when the inverted switching signal SWS has a logic high level, the current block switch 223a may connect the unit current source 221a to the current block path. Thus, the current cell 200a may discontinue the providing of the unit current to the current-voltage converter 150 of FIG. 1.

FIG. 3B is a circuit diagram illustrating another example of the current cell 200 of FIG. 2. Referring to FIG. 3B, a current cell 200a includes a switching signal generating unit 210b and a unit current providing unit 220b. The switching signal generating unit 210b includes a memory circuit 211b, a row select transistor 214b, and a column select transistor 215b. In the present exemplary embodiment, the memory circuit 211b may be a latch circuit including a first inverter 212b and a second inverter 213b. The switching signal generating unit 210b may further include a reset transistor 216b. The unit current providing unit 220b may include a unit current source 221b and a current providing switch 222b. The unit current providing unit 220b may further include a current block switch 223b.

Although FIG. 3A illustrates that the row select transistor 214a and the column select transistor 215a are serially connected between the input terminal of the first inverter 212a and the low power voltage VSS, the row select transistor 214b and the column select transistor 215b are serially connected between an input terminal of the second inverter 213b and a high power voltage VDD. For example, the row select transistor 214b may have a first source connected to the high power voltage VDD, a first gate to which an inverted row select signal RSS is applied, and a first drain connected to a second source of the column select transistor 215b. The column select transistor 215b may have the second source connected to the first drain of the row select transistor 214b, a second gate to which an inverted first column select signal CSS1 or an inverted second column select signal CSS2 is applied, and a second drain connected to an input terminal of the second inverter 213b. In another exemplary embodiment, the column select transistor 215b may be connected to the high power voltage VDD and the row select transistor 214b may be connected between the column select transistor 215b and the input terminal of the second inverter 213b.

When the inverted row select signal RSS and the inverted first column select signal CSS1 are simultaneously activated or the inverted row select signal RSS and the inverted second column select signal CSS2 are simultaneously activated, e.g., when the inverted row select signal RSS and the inverted first column select signal CSS1 simultaneously have a logic low level or the inverted row select signal RSS and the inverted second column select signal CSS2 simultaneously have a logic low level, the row select transistor 214b and the column select transistor 215b are simultaneously turned on. When the row select transistor 214b and the column select transistor 215b are simultaneously turned on, the switching signal SWS has a logic high level. Even when the row select transistor 214b and/or the column select transistor 215b are turned off, the memory circuit 211b may maintain the switching signal SWS and the inverted switching signal SWS, respectively, at a logic high level and a logic low level. Accordingly, the current providing switch 222b may connect the unit current source 221b to the current-voltage converter 150 of FIG. 1, and the current cell 200b may provide a unit current to the current-voltage converter 150 of FIG. 1.

The reset transistor 216b is turned on in response to an inverted reset signal RST. For example, when the inverted reset signal RST has a logic low level, the reset transistor 216b is turned on and a voltage of a logic high level is applied to the input terminal of the first inverter 212b. Accordingly, the inverted switching signal SWS has a logic high level. The first inverter 212b inverts a voltage of a logic high level to generate a switching signal SWS having a logic low level. In other words, the switching signal SWS is deactivated and the inverted switching signal SWS is activated. When the switching signal SWS is deactivated and the inverted switching signal SWS is activated, the current providing switch 222b is turned off and the unit current block switch 223b is turned on. Thus, the current block switch 223b may connect the unit current source 221b to a current block path. Thus, the current cell 200b may discontinue the providing of the unit current to the current-voltage converter 150 of FIG. 1.

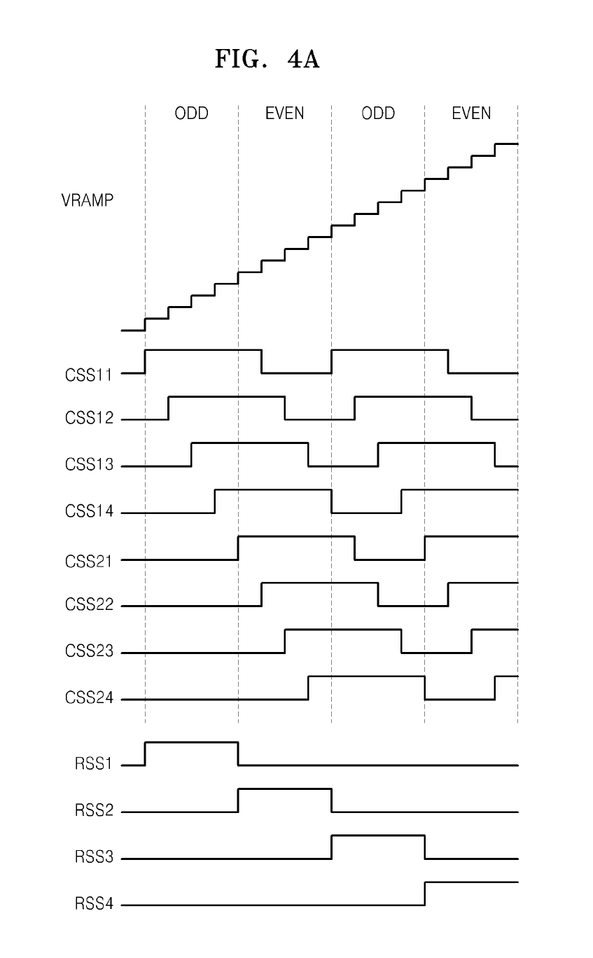

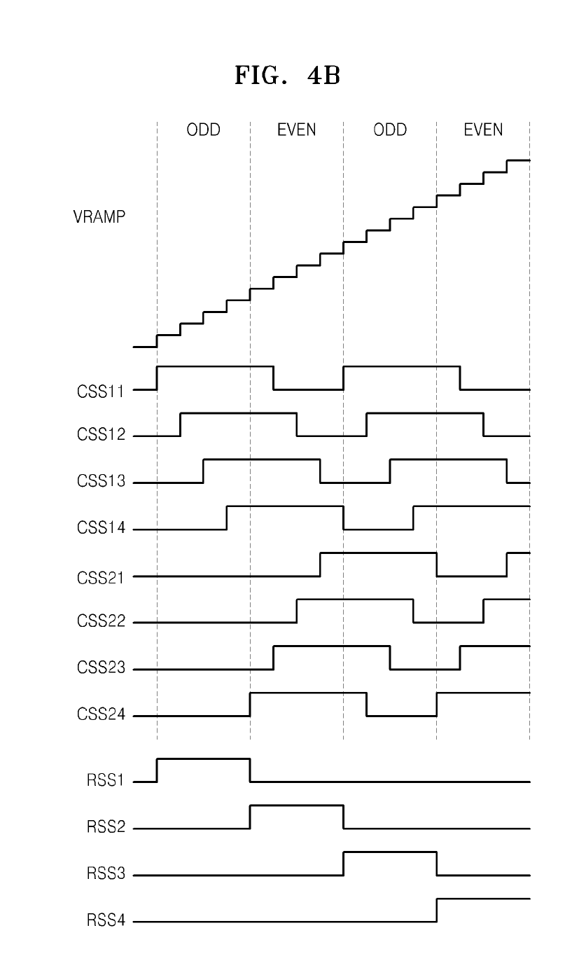

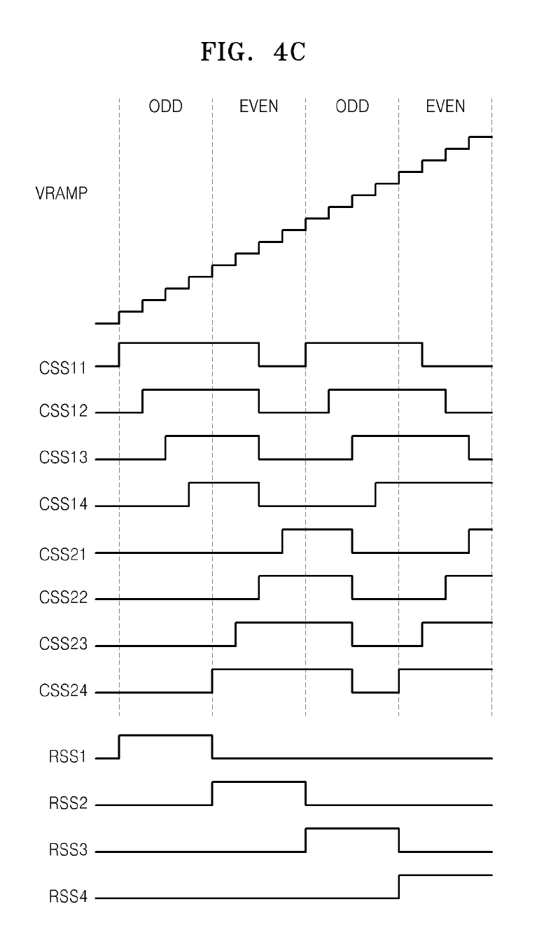

FIG. 4A is a timing diagram illustrating an operation of the ramp signal generator 100, according to an exemplary embodiment. Referring to FIGS. 1 and 4A, one or more row select signals RSS1, RSS2, RSS3, and RSS4 may be sequentially activated. While the row select signal RSS1 is activated, the first column select signals CSS11, CSS12, CSS13, and CSS14 may be sequentially activated. While the row select signal RSS2 is activated, the second column select signals CSS21, CSS22, CSS23, and CSS24 may be sequentially activated. Therefore, the ramp signal generator 100 may generate a ramp voltage VRAMP that increases according to the passage of time.

In this case, if the activated first column select signals CSS11, CSS12, CSS13, and CSS14 need to be deactivated when the row select signal RSS1 is activated in order to prepare activation of the current cells included in the second row on time when the row select signal RSS2 is activated, the duration time of activation of the first column select signals CSS11, CSS12, CSS13, and CSS14 may be shortened.

The ramp signal generator 100 according to the present exemplary embodiment may include a plurality of column decoders to facilitate extension of the activation time of the first column select signals CSS11, CSS12, CSS13, and CSS14. Accordingly, the activation time of the first column select signals CSS11, CSS12, CSS13, and CSS14 may be longer than that of the row select signal RSS1. Thus, the current cell may stably generate a unit current.

In this case, when the second column select signal CSS21 and the row select signal RSS2 are simultaneously activated, a glitch may occur. A ramp signal generator, according to another exemplary embodiment, may prevent occurrence of a glitch by ensuring there is a small difference between the time when the second column select signal CSS21 is activated and the time when the row select signal RSS2 is activated.

FIG. 4B is a timing diagram illustrating an operation of the ramp signal generator 100, according to an exemplary embodiment. Referring to FIGS. 1 and 4B, one or more row select signals RSS1, RSS2, RSS3, and RSS4 may be sequentially activated. While the row select signal RSS1 is activated, the first column select signals CSS11, CSS12, CSS13, and CSS14 may be sequentially activated. While the row select signal RSS2 is activated, the second column select signals CSS21, CSS22, CSS23, and CSS24 may be sequentially activated. Therefore, the ramp signal generator 100 may generate a ramp voltage VRAMP that increases according to the passage of time. In this case, while the row select signal RSS2 is activated, the second column select signals CSS21, CSS22, CSS23, and CSS24 may be activated in reverse order.

The first column select signals CSS11, CSS12, CSS13, and CSS14 and the second column select signals CSS21, CSS22, CSS23, and CSS24 may be deactivated in order of the activation of the current cells. By sequentially deactivating the column select signals, occurrence of a glitch that occurs when the column select signals are simultaneously deactivated may be prevented.

FIG. 4C is a timing diagram illustrating an operation of the ramp signal generator 100, according to an exemplary embodiment. Referring to FIGS. 1 and 4C, one or more row select signals RSS1, RSS2, RSS3, and RSS4 may be sequentially activated. While the row select signal RSS1 is activated, the first column select signals CSS11, CSS12, CSS13, and CSS14 may be sequentially activated. Also, the first column select signals CSS11, CSS12, CSS13, and CSS14 may be simultaneously deactivated.

Also, while the row select signal RSS2, the second column select signals CSS21, CSS22, CSS23, and CSS24 may be activated. Also, the second column select signals CSS21, CSS22, CSS23, and CSS24 may be simultaneously deactivated. As such, the ramp signal generator 100 may generate a ramp voltage VRAMP that increases over time.

The column select signals may be uniformly controlled by simultaneously deactivating the first column select signals CSS11, CSS12, CSS13, and CSS14 and the second column select signals CSS21, CSS22, CSS23, and CSS24.

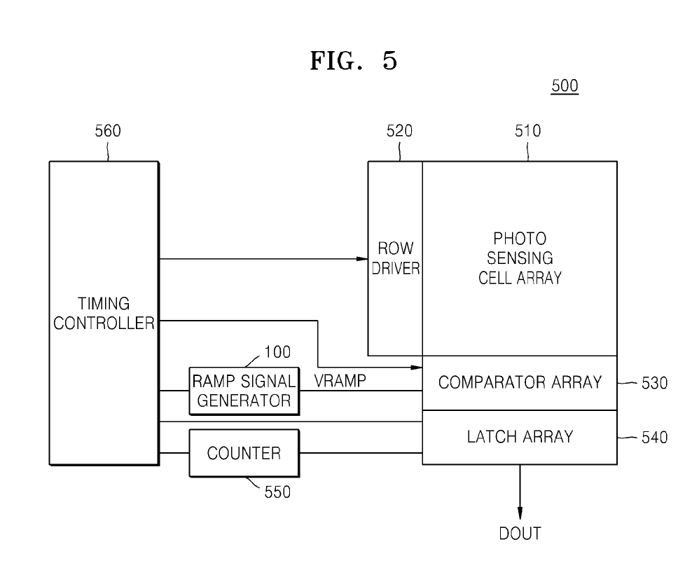

FIG. 5 is a block diagram illustrating an image sensor 500 according to an exemplary embodiment. Referring to FIG. 5, the image sensor 500 includes a plurality of photosensing cells 510, a row driver 520, the ramp signal generator 100 of FIG. 1, a counter 550, a comparator array 530, a latch array 540, and a timing controller 560.

The photosensing cells 510 may convert incident light to an electric signal. For example, each of the photosensing cells 510 may be a photodiode, a phototransistor, a photogate, a pinned photodiode (PPD), or a combination thereof. In the present exemplary embodiment, each of the photosensing cells 510 may be a 4-transistor structure including the photodiode, a transfer transistor, a reset transistor, an amplification transistor, and a select transistor. In another exemplary embodiment, each of the photosensing cells 510 may be a 1-transistor structure, a 3-transistor structure, or a 5-transistor structure, or a structure in which a plurality of pixels share some transistors.

The row driver 520 is electrically connected to rows of the photosensing cells 510, generates a drive signal, and provides the drive signal to each row of the photosensing cells 510. For example, the row driver 520 may select the photosensing cells 510 in units of rows.

The ramp signal generator 100 generates a ramp voltage VRAMP. The comparator array 530 is electrically connected to columns of the photosensing cells 510, receives electric signals from the photosensing cells 510, and receives the ramp signal VRAMP from the ramp signal generator 100. The comparator array 530 may compare an electric signal with the ramp signal VRAMP.

The counter 550 may generate a counting signal corresponding to the ramp signal VRAMP. For example, the counter 550 may start a counting operation when the ramp signal generator 100 starts a ramp voltage generation operation, and may increase the amplitude of a counting signal whenever a level of the ramp signal VRAMP increases. The latch array 540 may store the counting signal in response to an output signal of the comparator array 530. The comparator array 530 may output the counting signal as output data DOUT. In another exemplary embodiment, the image sensor 500 may further include an interpolator for interpolating the output data DOUT, and a data processing unit for processing the output data DOUT.

The timing controller 560 may control operation timing of the row driver 520, the ramp signal generator 100, the counter 550, the comparator array 530, and the latch array 540. The timing controller 560 may provide a timing signal and a control signal to the row driver 520, the ramp signal generator 100, the counter 550, the comparator array 530, and the latch array 540. The timing controller 560 may include the timing controller 140 of the ramp signal generator, as shown in FIG. 1.

The ramp signal generator 100 may include a plurality of column decoders and may make each column decoder activate a current cell corresponding to a different row. Therefore, a long time duration of a column select signal is facilitated. A malfunction that a current cell is not activated, because a column select signal is not recognized, may be prevented.

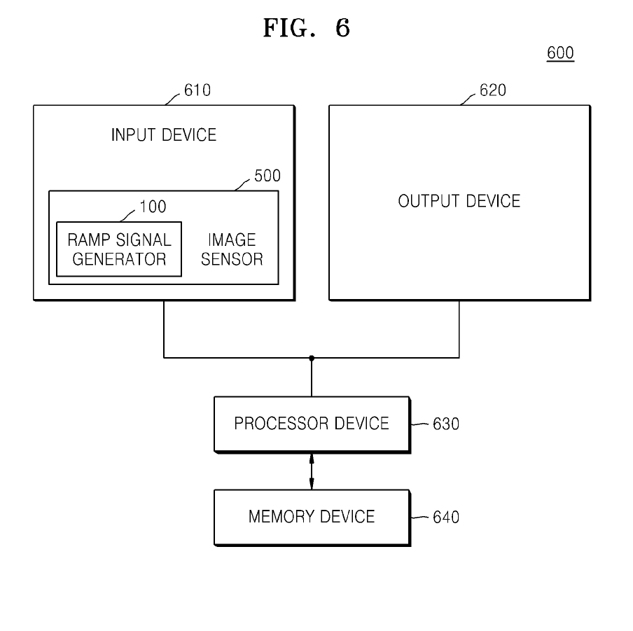

FIG. 6 is a block diagram illustrating an applied example of an electronic system 600 including the ramp signal generator 100. Referring to FIG. 6, the electronic system 600 may include an input device 610, an output device 620, a processor device 630, and a memory device 640. The processor device 630 may control the input device 610, the output device 620, and the memory device 640 via interfaces corresponding thereto.

The electronic system 600 may communicate with a video card, a sound card, a memory card, a USB card, etc., or may further include a port for communicating with another system. For example, the electronic system 600 may be a computer system, a camera system, a scanner, a navigation system for vehicles, a video phone, a monitoring system, an autofocus system, a tracking system, a motion detection system, an image stabilization system, or a system using an image sensor.

The input device 610 may include the image sensor 500 including the ramp signal generator 100 of the exemplary embodiments. In the present exemplary embodiment, the image sensor 500 may be integrated with the processor device 630 such as a microprocessor, a central processing unit (CPU), or a digital signal processor (DSP), or may be integrated with the memory device 640. The image sensor 500 may communicate with the processor device 630 via a communication link.

The processor device 630 may include at least any one of a microprocessor, a DSP, a microcontroller, and logic devices capable of performing a similar function thereto. The input device 610 and the output device 620 may include at least one device capable of inputting/outputting data.

The ramp signal generator 100 included in the image sensor 500 includes a plurality of column decoders and may make each column decoder activate a current cell corresponding to a different row. Therefore, a long time duration of a column select signal is facilitated. A malfunction that a current cell is not activated because a column select signal is not recognized may be prevented.

While exemplary embodiments has been particularly shown and described with reference to exemplary embodiments thereof, it will be understood that various changes in form and details may be made therein without departing from the spirit and scope of the following claims.

What is claimed is:

1. A ramp signal generator comprising:
a row decoder which receives a row control signal from a timing controller and generates one or more row select signals;
a first column decoder which receives a first column control signal from the timing controller and generates one or more first column select signals;
a second column decoder which receives a second column control signal from the timing controller and generates one or more second column select signals; and
a current cell array which is activated by the one or more first column select signals, the one or more second column select signals, and the one or more row select signals, comprises at least one current cell which generates at least one unit current, and generates an output current by summing the generated at least one unit current,
wherein the one or more first column select signals and the one or more second column select signals activate current cells included in different rows.

2. The ramp signal generator of claim 1, wherein the one or more first column select signals activate the current cells in an odd-numbered row of the current cell array, and the one or more second column select signals activate the current cells in an even-numbered row of the current cell array.

3. The ramp signal generator of claim 1, wherein the at least one current cell continuously generates the at least one unit current even when the one or more first column select signals, the one or more second column select signals, and the one or more row select signals are deactivated.

4. The ramp signal generator of claim 1, further comprising a current-voltage converter that converts the output current of the current cell array to a ramp signal.

5. The ramp signal generator of claim 1, wherein the current cell array comprises one or more current cells in m-numbered rows and n-numbered columns, the first column decoder turns on the current cells in a first row in order from a first column to an n-th column, and the second column decoder turns on the current cells in a second row in order from the n-th column to the first column.

6. The ramp signal generator of claim 5, further comprising:
a third column decoder which receives a third column control signal from the timing controller and generates one or more third column select signals; and
a fourth column decoder which receives a fourth column control signal from the timing controller and generates one or more fourth column select signals,
wherein the third column decoder turns on the current cells in a third row in order from the first column to the n-th column, and the fourth column decoder turns on the current cells in a fourth column in order from the n-th column to the first column.

7. The ramp signal generator of claim 1, wherein a number of the one or more first column select signals and the one or more second column select signals correspond to a number of the current cells included in the current cell array belonging to a same row.

8. The ramp signal generator of claim 1, wherein the first column decoder and the second column decoder do not respectively simultaneously deactivate the one or more first column select signals and the one or more second column select signals corresponding to the current cells.

9. The ramp signal generator of claim 1, wherein the first column decoder and the second column decoder deactivate the one or more first column select signals and the one or more second column select signals respectively, corresponding to the current cells in order of the activation of the current cells.

10. The ramp signal generator of claim 1, wherein each of the current cells comprises:
a switching signal generating unit which activates a switching signal in response to the one or more first column select signals, the one or more second column select signals, and the one or more row select signals, and maintaining an active state of the switching signal; and
a unit current providing unit which provides the at least one unit current in response to the switching signal.

11. The ramp signal generator of claim 10, wherein the switching signal generating unit comprises:
a row select switch which is turned on in response to the one or more row select signals;
a column select switch which is serially connected to the one or more row select switch and turned on in response to the one or more first column select signals or the one or more second column select signals; and
a memory circuit which activates the switching signal and maintains the active state of the switching signal when the row select switch and the column select switch are turned on.

12. The ramp signal generator of claim 11, wherein the switching signal generating unit further comprises a reset switch which is turned on in response to a reset signal, and the memory circuit deactivates the switching signal when the reset switch is turned on.

13. The ramp signal generator of claim 10, wherein the unit current providing unit comprises:
a unit current source which provides the at least one unit current; and
a current providing switch which connects the unit current source to a current-voltage converter which converts the output current of the current cell array to a ramp signal.

14. An image sensor comprising:
the ramp signal generator of claim 1;
one or more photosensing cells which converts incident light to an electric signal;
a row driver which generates a drive signal to activate the one or more photosensing cells in units of rows;
a counter which generates a counting signal corresponding to the ramp signal;
a comparator array which connects to the one or more photosensing cells in a column direction and compares the electric signal to the ramp signal;
a latch array which stores the counting signal corresponding to an output signal of the comparator array; and
a timing controller which provides control signals to the row driver, the ramp signal generator, the counter, the comparator array, and the latch array.

15. The image sensor of claim 14, wherein the first column decoder and the second column decoder do not respectively simultaneously deactivate the one or more first column select signals and the one or more second column select signals, corresponding to the current cells when the one or more first column select signals and the one or more second column select signals are deactivated.

16. A method of generating a ramp signal, the method comprising:
receiving a row control signal, and generating one or more row select signals;
receiving a first column control signal, and generating one or more first column select signals;
receiving a second column control signal, and generating one or more second column select signals;
activating a current cell array by the one or more first column select signals, the one or more second column select signals, and the one or more row select signals;
generating at least one unit current; and
generating an output current by summing the generated at least one unit current, wherein the one or more first column select signals and the one or more second column select signals activate current cells included in different rows.

17. The method of claim 16, further comprising:
converting the output current of the current cell array to a ramp signal.

18. The method of claim 16, further comprising:
receiving a third column control signal, and generating one or more third column select signals;
receiving a fourth column control signal, and generating one or more fourth column select signals;
turning on the current cells in a third row in order from a first column to an n-th column; and
turning on the current cells in a fourth column in order from the n-th column to the first column.

19. The method of claim 16, wherein the one or more first column select signals and the one or more second column signals are not simultaneously deactivated when the one or more first column select signals and the second column select signals are deactivated.
